(19) United States
(12) Patent Application Publication
(10) Pub. No.: US 2020/0305289 A1
(43) Pub. Date: Sep. 24, 2020

(54) FLEXIBLE SUBSTRATE AND METHOD FOR FABRICATING THE SAME

(71) Applicant: PHOENIX & CORPORATION, Grand Cayman (KY)

(72) Inventors: Chun-Hsien Yu, Hsinchu County (TW); Hsien-Ming Tsai, Hsinchu County (TW)

(21) Appl. No.: 16/356,039

(22) Filed: Mar. 18, 2019

(51) Int. Cl. H05K 3/46; H05K 1/02

(52) U.S. Cl. CPC H05K 3/4691; H05K 3/4682; H05K 2203/308; H05K 1/0278; H05K 3/4647

(57) ABSTRACT

A flexible substrate is provided, including a coreless substrate body having a flexible section, and an additional element formed on the substrate body and having a through hole exposing the flexible section, thereby reducing the overall thickness of the flexible substrate and meeting the thinning requirement

### BACKGROUND

### 1. Technical Field The present disclosure relates to packaging substrates, and, more particularly, to a flexible substrate and a method for fabricating the same.

### 2. Description of Related Art

Currently, rigid-flexible circuit boards are widely applied in smartphone boards, optoelectronic boards, CMOS, battery modules and wearable devices. In a conventional rigid-flexible circuit board, a soft board structure is encapsulated by a rigid board structure, a portion of the soft board structure that needs to be flexed is exposed from the rigid board structure, and interlayer connections are used to replace conventional surface mounting, thereby saving spaces, simplifying the assembly process and effectively reducing noises transmitted from the soft board structure to the rigid board structure.

Therefore, the application of rigid-flexible circuit boards in electronic products (especially in lighter, thinner, shorter and smaller mobile devices and wearable devices) is rapidly increasing due to their advantages of good reliability, easy assembly and noise suppression.

FIGS. 1A to 1D are schematic cross-sectional views showing a method for fabricating a rigid-flexible packaging substrate 1 according to the prior art.

Referring to FIGS. 1A to 1B, a soft board 10 having a flexible section A is provided and a rigid board 11 having a through hole 110 is attached to the two opposite sides of the soft board 10. The through hole 110 corresponds in position to the flexible section A so as to expose the flexible section A.

The soft board 10 has a core layer 10a, first circuit layers 10b formed on the two opposite sides of the core layer 10a, adhesive layers 10c covering the first circuit layers 10b, and protection films 10d covering the adhesive layers 10c. For example, the core layer 10a and the first circuit layers 10b are made of a copper clad laminate (CCL).

The rigid board 11 had a rigid substrate 11a, a metal layer 11b formed on one side of the rigid substrate 11a, and a pure adhesive layer 11c formed on the other side of the rigid substrate 11a. By performing a mechanical drilling process, the through hole 110a is formed in the rigid board 11 to penetrate the rigid substrate 11a, the metal layer 11b and the pure adhesive layer 11c. Further, the pure adhesive layer 11c is attached to the protection film 10d of the soft board 10.

Referring to FIG. 1C, by performing a mechanical drilling or laser ablation process, a plurality of through holes 100 are formed to penetrate the soft board 10 and the rigid boards 11.

Referring to FIG. 1D, by using the metal layers 11b as current conductive paths, an electroplating process is performed to electroplate a conductive material 12a on the metal layers 11b and walls of the through holes 100. Then, the metal layers 11b and the conductive material 12a are patterned and etched to form second circuit layers 12 on the rigid substrates 11a and hollow conductive through holes 13 in the through holes 100. The conductive through holes 13 electrically connect conductive pads 101 of the first circuit layers 10b and the second circuit layers 12. Thereafter, solder mask layers 14, such as ink or green paint, are formed on the rigid substrates 11a and the second circuit layers 12 and in the conductive through holes 13 and portions of the second circuit layers 12 are exposed from the solder mask layers 14. But the solder mask layers 14 are not formed in the through holes 110.

Therefore, the rigid-flexible packaging substrate 1 is flexible at the flexible section A exposed from the through holes 110.

However, the soft board 10 and the rigid boards 11 cannot be aligned accurately due to great interlayer size variations of the soft board 10 and limitations of the attachment process. In particular, the pure adhesive layer 11c may cause a positional deviation of the rigid board 11, resulting in an interlayer alignment accuracy of about +/−100 um between the soft board 10 and the rigid board 11. As such, the area of the conductive pads 101 of the soft board 10 must be increased to prevent a positional deviation of the through holes and hence ensure the electrical connection between the conductive through holes 13 and the conductive pads 101. As such, the available area for other functional circuits of the first circuit layers 10b is reduced and consequently, the width of the soft board 10 needs to be increased or the circuit function of the soft board 10 needs to be reduced. On the other hand, if the area of the conductive pads 101 is not increased, the distance t between the conductive pads 101 and surrounding circuits must be increased so as to prevent a short circuit from occurring due to the positional deviation of the through holes. But it cannot meet the fine pitch requirement.

Further, since the rigid boards 11 are attached to the soft board 10 through the pure adhesive layer 11c, defects such as adhesive overflows e (at corners of the through holes 110 of FIG. 1B), shorts or edge sinks may occur at interfaces between the soft board 10 and the rigid boards 11, thus adversely affecting the subsequent attachment process and the flexibility of the packaging substrate.

In addition, limited by the core layer 10a of the soft board 10, the thickness of the rigid boards 11 (a certain thickness is needed for required rigidity), and the second circuit layers 12, it is difficult to reduce the thickness H of the packaging substrate 1 to be less than 0.3 mm. Therefore, the packaging substrate 1 cannot meet the thinning requirement.

FIGS. 2A to 2D are schematic cross-sectional views showing another method for fabricating a rigid-flexible packaging substrate 2 according to the prior art.

Referring to FIGS. 2A to 2B, a soft board 20 having a flexible section A is provided and a dielectric layer 21 having a through hole 210 is laminated on each of the two opposite sides of the soft board 20. The through hole 210 corresponds in position to the flexible section A so as to expose the flexible section A. Then, metal layers 21b made of such as copper are formed on the dielectric layers 21, walls of the through holes 210 and the flexible section A.

The soft board 20 has a core layer 20a, first circuit layers 20b formed on the two opposite sides of the core layer 20a, adhesive layers 20c formed on the flexible section A, and protection films 20d covering the adhesive layers 20c. For example, the core layer 20a and the first circuit layers 20b are made of a copper clad laminate

The dielectric layers 21 are made of prepreg. By performing a mechanical drilling process, the through holes 210 are formed to penetrate the dielectric layers 21. The dielectric layers 21 are bonded to the core layer 20a, the first circuit layers 20b and portions of the protection films 20d of the soft board 20.

Referring to FIG. 2C, by performing a mechanical drilling or laser ablation process, a plurality of through holes 200 are formed to penetrate the soft board 20, the dielectric layers 21 and the metal layers 21.

Referring to FIG. 2D, by using the metal layers 21b as current conductive paths, an electroplating process is performed to electroplate a conductive material 22a on the metal layers 21b and walls of the through holes 200. Then, the metal layers 21b and the conductive material 22a are patterned and etched to form second circuit layers 22 on the dielectric layers 22a and hollow conductive through holes 23 in the through holes 200. The conductive through holes 23 electrically connect conductive pads 201 of the first circuit layers 20b and the second circuit layers 22. Thereafter, solder mask layers 24 such as ink or green paint are formed on the dielectric layers 21 and the second circuit layers 22 and in the conductive through holes 23, and portions of the second circuit layers 22 are exposed form the solder mask layers 24. But the solder mask layers 24 are not formed in the through holes 210.

Therefore, the rigid-flexible packaging substrate 2 is flexible at the flexible section A exposed from the through holes 210.

However, since interlayer size variations of the soft board 20 are great and lamination of the dielectric layers 21 on the soft board 20 is performed under high temperature and high pressure, an irregular deformation may occur to the packaging substrate 2 and a poor interlayer alignment accuracy (about +/−100 um) may occur between the soft board 20 and the dielectric layers 21. As such, the area of the conductive pads 201 of the soft board 20 must be increased to prevent a positional deviation of the through holes and hence ensure the electrical connection between the conductive through holes 23 and the conductive pads 201. As such, the available area for other functional circuits of the first circuit layers 20b is reduced and consequently, the width of the soft board 20 needs to be increased or the circuit function of the soft board 20 needs to be reduced. On the other hand, if the area of the conductive pads 201 is not increased, the distance t between the conductive pads 201 and surrounding circuits must be increased so as to prevent a short circuit from occurring due to the positional deviation of the through holes. But it cannot meet the fine pitch requirement.

Further, after lamination of the dielectric layer 21, the rigid-flexible interface of the packaging substrate 2 may bulge due to the existence of two kinds of materials (the dielectric layer 21 of prepreg and the protection film 20d), thus adversely affecting the subsequent attachment process and the flexibility of the packaging substrate.

In addition, limited by the core layer 20a of the soft board 20, the thickness of the protection films 20d (a certain thickness is needed to prevent cracking of the protection films 20d when being flexed), the thickness of the dielectric layers 21 (a certain thickness is needed for required rigidity), and the second circuit layers 22, it is difficult to reduce the thickness h of the packaging substrate 2 to be less than 0.25 mm. Therefore, the packaging substrate 2 cannot meet the thinning requirement.

FIGS. 3A to 3E are schematic cross-sectional views showing a further method for fabricating a rigid-flexible packaging substrate 3 according to the prior art.

Referring to FIG. 3A, a rigid board 311 having an opening 311 is provided. The rigid board 31 has a rigid substrate 31a and internal circuit layers 31c formed on the two opposite sides of the rigid substrate 31a. For example, the rigid substrate 31a and the internal circuit layers 31c are made of a copper clad laminate, and the opening 311 is formed by mechanical drilling.

Referring to FIG. 3B, a soft board 30 having a flexible section A is disposed in the opening 311. The soft board 30 has a core layer 30a, first circuit layers 30b formed on the two opposite sides of the core layer 30a, adhesive layers 30c formed on the flexible section A, and protection films 30d covering the adhesive layers 30c.

Referring to FIG. 3C, dielectric layers 31d each having a through hole 310 are laminated on the two opposite sides of the rigid board 31 and the soft board 30, and the through holes 310 correspond in position to the flexible section A so as to expose the flexible section A. Then, metal layers 31b made of such as copper are formed on the dielectric layers 31d, walls of the through holes 310 and the flexible section A. Thereafter, a plurality of through holes 300 are formed to penetrate the rigid board 31, the dielectric layers 31d and the metal layers 31b, and a plurality of conductive vias 301 are formed to penetrate the dielectric layers 31d and the metal layers 31b to expose portions of the first circuit layers 30b.

The dielectric layers 31d are made of prepreg. The dielectric layers 31 are bonded to the rigid board 31, and portions of the first circuit layers 30b and portions of the protection films 30d of the soft board 30.

Referring to FIG. 3D, by using the metal layers 31b as current conductive paths, an electroplating process is performed to electroplate a conductive material 32a on the metal layers 31b and walls of the through holes 300 and in the conductive vias 300. Then, the metal layers 31b and the conductive material 32a are patterned and etched to form second circuit layers 32 on the dielectric layers 31d and conductive through holes 33 in the through holes 300. The conductive through holes 33 electrically connect the internal circuit layers 31c and the second circuit layers 32. Thereafter, circuit structures 35 are formed on the dielectric layers 31d and electrically connected to the second circuit layers 32. Then, solder mask layers 34 such as ink or green paint are formed on the circuit structures 35 and portions of the circuit structures 35 are exposed from the solder mask layers 34.

Referring to FIG. 3E, the portions over the through holes 310 (i.e., the circuit structures 35, the conductive material 32a and the metal layers 31b) are removed by mechanical cutting to expose the flexible section A (i.e., expose the protection films 30d).

Therefore, the rigid-flexible packaging substrate 3 is flexible at the flexible section A.

However, since the second circuit layers 32 are formed by etching the metal layers 31b and the conductive material 32a, the line width/pitch of the second circuit layers 32 is limited by the fabrication process and cannot be less than 40/40 um.

Further, after lamination of the dielectric layers 31d, an edge bulge or prepreg overflow may occur at the rigid-flexible interface of the packaging substrate 3 due to the existence of two kinds of materials (the dielectric layers 3d1 and the protection films 30d), thus adversely affecting the subsequent attachment process and the flexibility of the packaging substrate.

In addition, since the rigid board 31 corresponds in thickness to the soft board 30 (the soft board 30 needs to have a certain thickness to prevent cracking when being flexed), it is difficult to reduce the thickness H of the packaging substrate 3 to be less than 0.25 mm. Therefore, the packaging substrate 3 cannot meet the thinning requirement

FIG. 4 is a schematic cross-sectional view showing another method for fabricating a rigid-flexible packaging substrate 4 according to the prior art.

Referring to FIG. 4, circuit boards 40 each having a flexible section A are laminated on the two opposite sides of a core board 9. Each of the circuit boards 40 has a circuit layer 40b, a soft portion 40c and a first dielectric layer 40d. The circuit layer 40b is laminated on the core board 9. The first dielectric layer 40d has an opening 400 corresponding in position to the flexible section A for exposing the soft portion 40c. Then, second dielectric layers 41 each having a through hole 410 and protection films 90 are sequentially laminated on the circuit boards 40 according to the practical need.

As such, the packaging substrate 4 is flexible at the flexible section A and the line width/pitch of the circuit layers 40b are not limited as described above.

However, since two kinds of materials (the soft portions 40c and the first dielectric layers 40d) exist at the rigid-flexible interface of the packaging substrate 4, after lamination of the second dielectric layers 41, an edge bulge may occur in the openings 400 (or the through holes 410) due to an uneven stress distribution. As such, the subsequent attachment process and the flexibility of the packaging substrate are adversely affected.

Further, the core board 9 hinders thinning of the packaging substrate 4.

Therefore, how to overcome the above-described drawbacks has become critical.

### SUMMARY

In view of the above-described drawbacks, the present disclosure provides a flexible substrate, which comprises: a coreless substrate body having a flexible section and at least a dielectric layer, wherein the dielectric layer is made of a molding compound or a primer; and an additional element formed on the substrate body and having a through hole exposing the flexible section, wherein the through hole and the flexible section form a cavity.

In an embodiment, the substrate body further has a circuit structure bonded to the dielectric layer.

In an embodiment, the additional element further has an insulating layer and a conductive post embedded in the insulating layer.

In an embodiment, the insulating layer is made of a dielectric material, such as a molding compound or a primer.

In an embodiment, the additional element is a metal sheet.

The present disclosure further provides a method for fabricating a flexible substrate, which comprises: providing a coreless substrate body having a flexible section and at least a dielectric layer, wherein the dielectric layer is made of a molding compound or a primer; forming an additional element on the substrate body, wherein the additional element has an insulating layer, a conductive post embedded in the insulating layer, and a block penetrating the additional element; and removing the block to form in the additional element a through hole exposing the flexible section, wherein the through hole and the flexible section form a cavity.

In an embodiment, the substrate body further has a circuit structure bonded to the dielectric layer.

In an embodiment, the insulating layer is made of a dielectric material, such as a molding compound or a primer.

The present disclosure further provides another method for fabricating a flexible substrate, which comprises: forming a coreless substrate body on a carrier, wherein the substrate body has a flexible section and at least a dielectric layer, and the dielectric layer is made of a molding compound or a primer; and removing a portion of the carrier to form a through hole penetrating the carrier and exposing the flexible section, allowing the carrier having the through hole to serve as an additional element, wherein the through hole and the flexible section form a cavity.

In an embodiment, the substrate body further has a circuit structure bonded to the dielectric layer.

In an embodiment, the carrier is a metal sheet.

Therefore, by providing additional elements and substrate structures that are different from the prior art, the present disclosure greatly improves the circuit density of rigid-flexible board structures and reduces the overall thickness of substrates. The present disclosure is applicable to high-end mobile devices that require reduced thicknesses and complicated (or multi-functional) circuits.

### BRIEF DESCRIPTION OF DRAWINGS

FIGS. 1A to 1D are schematic cross-sectional views showing a method for fabricating a rigid-flexible packaging substrate according to the prior art;

FIGS. 2A to 2D are schematic cross-sectional views showing another method for fabricating a rigid-flexible packaging substrate according to the prior art;

FIGS. 3A to 3E are schematic cross-sectional views showing a further method for fabricating a rigid-flexible packaging substrate according to the prior art;

FIG. 4 is a schematic cross-sectional view showing another method for fabricating a rigid-flexible packaging substrate according to the prior art;

FIGS. 5A to 5F are schematic cross-sectional views showing a method for fabricating a flexible substrate according to a first embodiment of the present disclosure;

FIG. 5G is a schematic top view of FIG. 5F;

FIGS. 6A to 6C are schematic cross-sectional views showing a method for fabricating a flexible substrate according to a second embodiment of the present disclosure; and

FIGS. 7A to 7B are schematic cross-sectional views showing a method for fabricating a flexible substrate according to a third embodiment of the present disclosure.

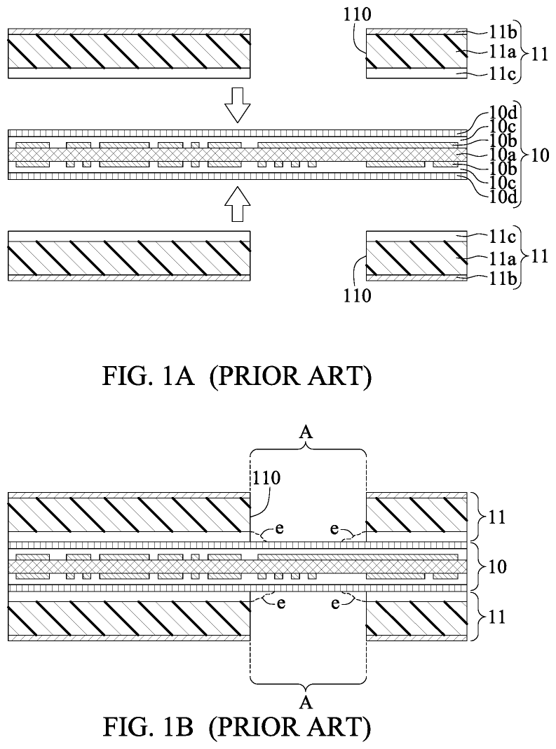

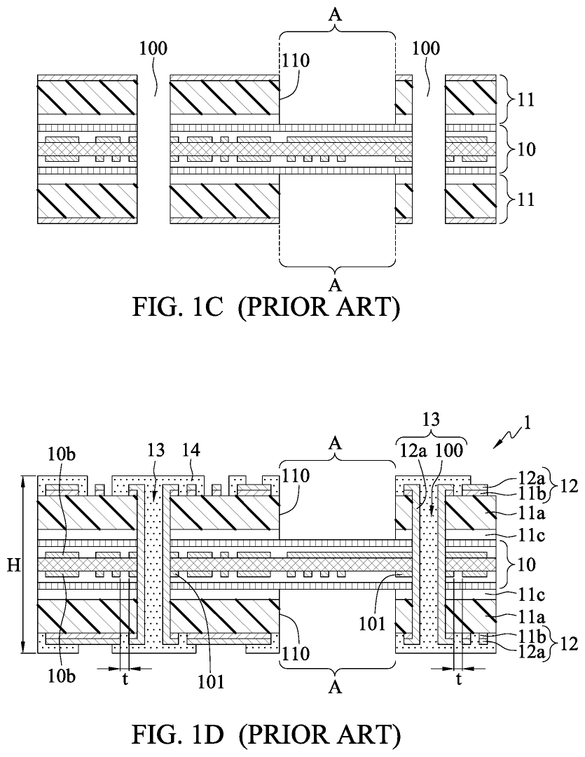

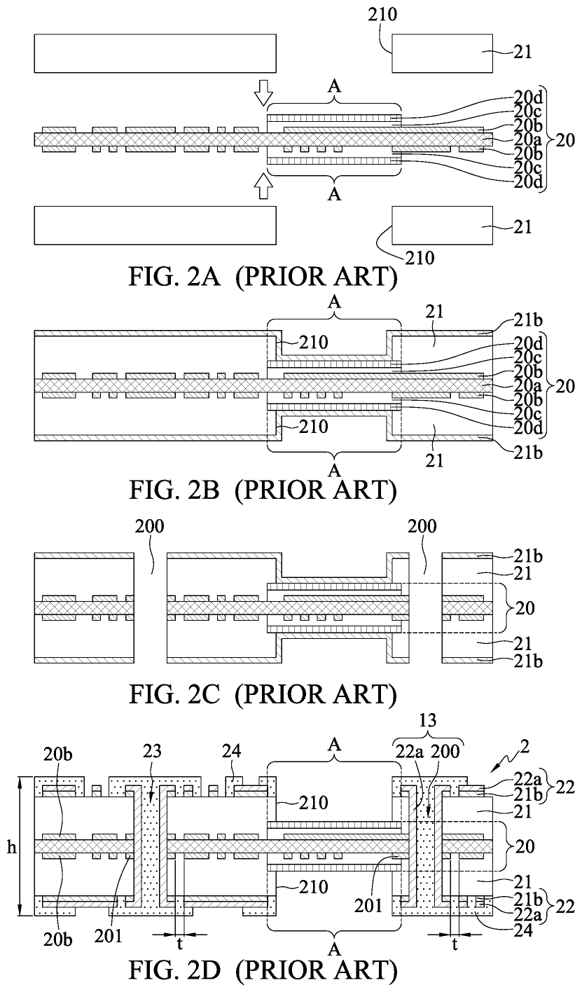

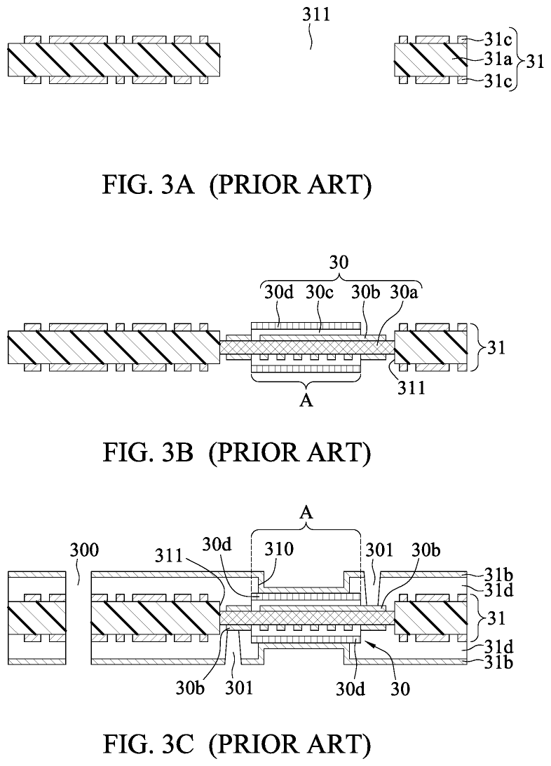

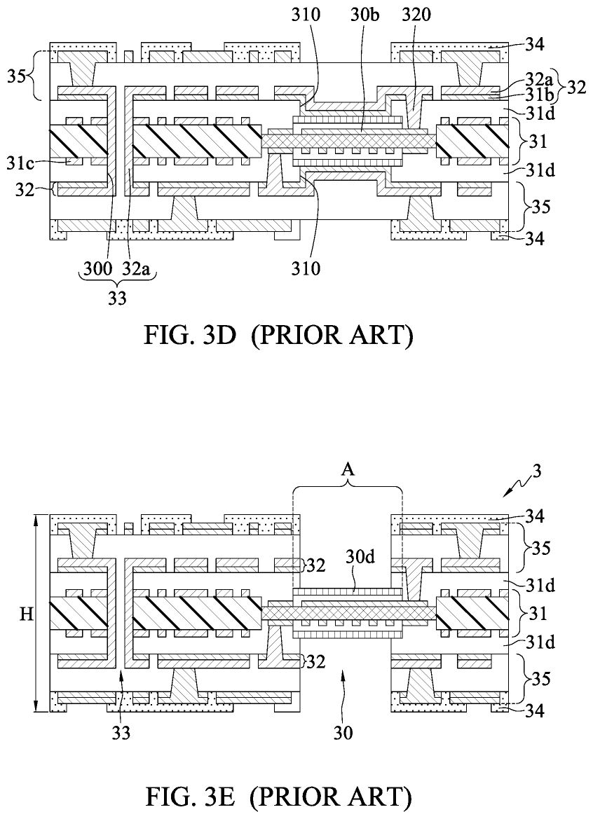

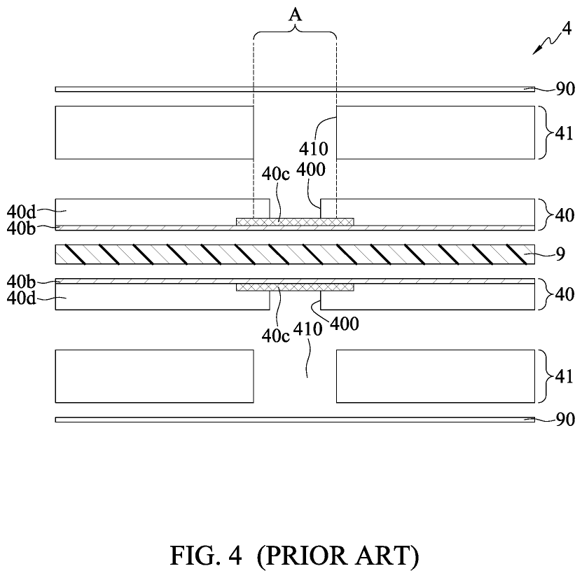

### DETAILED DESCRIPTION OF EMBODIMENTS

The following illustrative embodiments are provided to illustrate the disclosure of the present disclosure, these and other advantages and effects can be apparent to those in the art after reading this specification. It should be noted that all the drawings are not intended to limit the present disclosure.

Various modifications and variations can be made without departing from the spirit of the present disclosure. Further, terms such as “first”, “second”, “on”, “a” etc. are merely for illustrative purposes and should not be construed to limit the scope of the present disclosure.

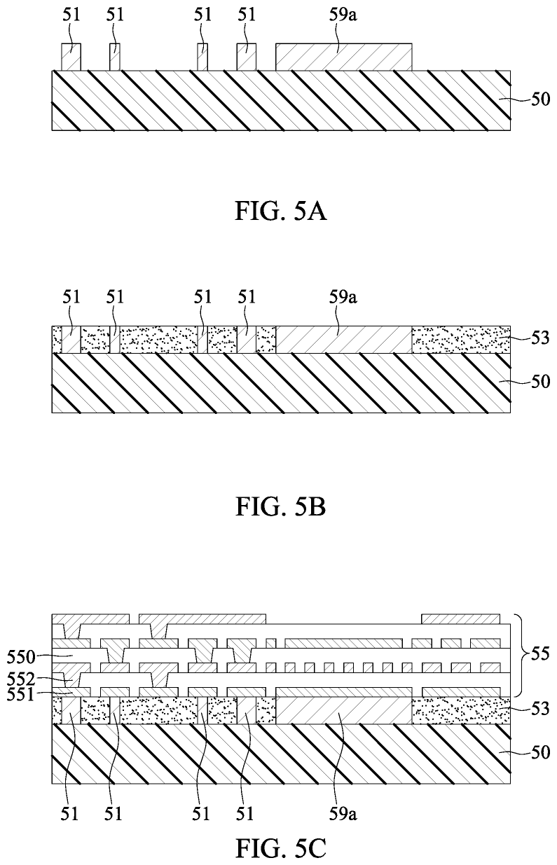

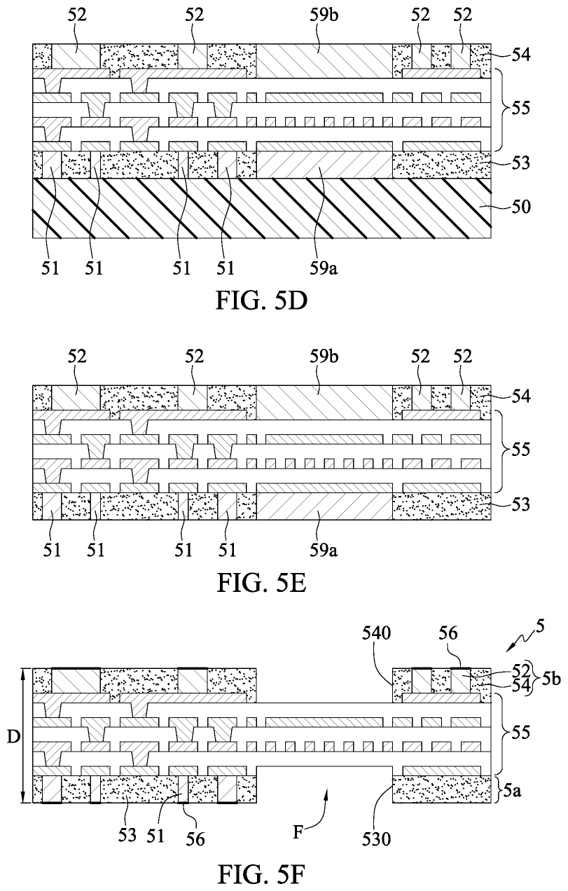

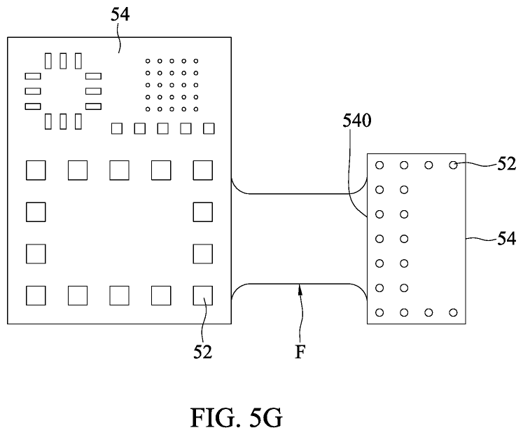

FIGS. 5A to 5F are schematic cross-sectional views showing a method for fabricating a flexible substrate 5 according to a first embodiment of the present disclosure.

Referring to FIG. 5A, a plurality of first conductive posts 51 and a block 59a are disposed on a carrier 50 through a patterning process.

In an embodiment, the carrier 50 is metal, a semiconductor or an insulating substrate.

The first conductive posts 51 and the block 59a are made of metal, such as copper. The first conductive posts 51 and the block 59a can be made of the same or different materials.

Referring to FIG. 5B, a first insulating layer 53 is formed on the carrier 50 to encapsulate the first conductive posts 51 and the block 59a. The surfaces of the first conductive posts 51 and the block 59a are flush with the surface of the first insulating layer 53 so as to be exposed from the first insulating layer 53. The block 59a penetrates the first insulating layer 53.

In an embodiment, the first insulating layer 53 serves as a rigid portion and is formed on the carrier 50 by molding, coating or lamination. The first insulating layer 53 is made of a dielectric material, such as an epoxy resin containing a molding compound or a primer, such as an epoxy molding compound. The epoxy molding compound contains 70 to 90 wt % of a filler.

Referring to FIG. 5C, a substrate body 55 is disposed on the first insulating layer 53 and electrically connected to the first conductive posts 51.

In an embodiment, the substrate body 55 is coreless and formed through a circuit built-up process. The substrate body 55 has at least a dielectric layer 550 formed by coating, a circuit layer 551 bonded to the dielectric layer 550, and a plurality of conductors 552 formed in the dielectric layer 550 and electrically connected to the circuit layer 551.

In another embodiment, the substrate body 55 is formed by molding. In yet another embodiment, a circuit layer 551 is formed on the first insulating layer 53 and then a plurality of conductive posts 551 are disposed on the circuit layer 551. Thereafter, the dielectric layer 550 is formed by molding to encapsulate the circuit layer 551 and the conductive posts. The conductive posts serve as the conductors 552.

The dielectric layer 550 serves as a soft portion. The dielectric layer 550 and the first insulating layer 53 can be made of the same or different materials. In an embodiment, the dielectric layer 550 and the first insulating layer 53 are made of the same or different kinds of epoxy resin.

Referring to FIG. 5D, a plurality of second conductive posts 52 and a block 59b are disposed on the substrate body 55 and a second insulating layer 54 is formed on the substrate body 55 to encapsulate the second conductive posts 52 and the block 59b. The surfaces of the second conductive posts 52 and the block 59b are flush with the surface of the second insulating layer 54 so as to be exposed from the second insulating layer 54. The block 59b penetrates the second insulating layer 54.

In an embodiment, the second conductive posts 52 and the block 59b are made of metal, such as copper. The second conductive posts 52 and the block 59b can be made of the same or different materials.

Further, the second insulating layer 54 serves as a rigid portion and is formed by molding, coating or lamination. The second insulating layer 54 is made of a dielectric material, such as an epoxy resin containing a molding compound or a primer, such as an epoxy molding compound. The epoxy molding compound contains 70 to 90 wt % of a filler.

Further, the second insulating layer 54 and the first insulating layer 53 can be made of the same or different materials, and the second insulating layer 54 and the dielectric layer 550 can be made of the same or different materials.

Referring to FIGS. 5E and 5G, the carrier 50 is removed by stripping and the blocks 59a, 59b are removed by etching. As such, a first through hole 530 is formed in the first insulating layer 53 and a second through hole 540 is formed in the second insulating layer 54. The substrate body 55 is exposed from the first and second through holes 530, 540 to serve as a flexible section F, wherein the first through hole 530 and the flexible section F form a cavity, and the second through hole 540 and the flexible section F form another cavity. The first conductive posts 51 and the first insulating layer 53 can be regarded as an additional element 5a, and the second conductive posts 52 and the second insulating layer 54 can be regarded as another additional element 5b.

In an embodiment, when the block 59a is removed, a portion of the substrate body 55 is also removed and hence the first through hole 530 extends into the substrate body 55. Similarly, the second through hole 540 extends into the substrate body 55.

Subsequently, a surface treatment layer 56 can be formed on the first and second conductive posts 51, 52 according to the practical need.

Therefore, the substrate body 55 is directly formed on the first insulating layer 53 (i.e., the dielectric layer 550 is coated on the first insulating layer 53) to replace the conventional lamination or attachment process. At the rigid-flexible interface of the flexible substrate 5, two layers of epoxy resin are directly bonded so as to overcome the conventional drawbacks such as adhesive overflows, shorts and bulges and increase the interlayer alignment accuracy to +/−25 um.

Further, the coreless substrate body 55 greatly reduces the overall thickness of the flexible substrate 5. Compared with a conventional four-layer board (generally having a thickness of a bout 0.25 mm), a four-layer board according to the present disclosure has a thickness D less than 0.2 mm. In an embodiment, the four-layer board has a thickness of 0.16 mm.

Furthermore, since the circuit layer 551 is formed by electroplating instead of metal etching, the edge of the circuit layer 551 is flat and straight, thereby overcoming the conventional foot problem caused by etching and facilitating impedance control. Further, the width/pitch of the circuit layer 551 can be reduced to be less than 20/20 um.

In addition, the flexible section F is fabricated by image transfer in combination with pattern electroplating copper (blocks 59a, 59b) and etching of copper (blocks 59a, 59b). Therefore, the shape, size and accuracy of the flexible section F are not limited by the conventional mechanical machining process, thereby improving the freedom of the structural design. In an embodiment, a plurality of flexible sections F having any shape can be fabricated at the same time. Further, the blocks 59a, 59b and the first and second conductive posts 51, 52 can be fabricated together to reduce the fabrication cost.

Furthermore, the outermost conductive pads of the flexible substrate 5 are copper posts (i.e., the first and second conductive posts 51, 52) and the dielectric material (i.e., the first and second insulating layers 53, 54) is used to replace the conventional solder mask layers. As such, the present disclosure strengthens the bonding between the conductive pads and the dielectric material, increases the subsequent wire bonding strength, and improves the product reliability and packaging capability.

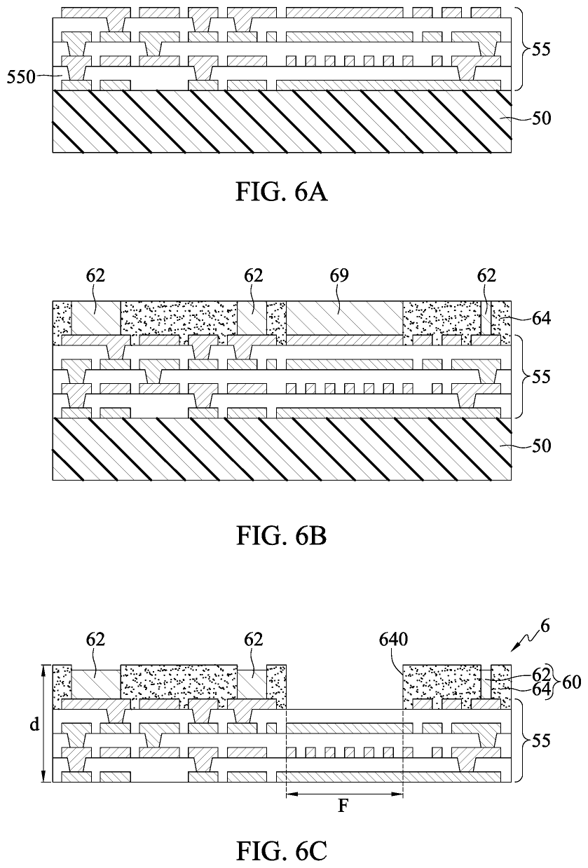

FIGS. 6A to 6C are schematic cross-sectional views showing a method for fabricating a flexible substrate 6 according to a second embodiment of the present disclosure. The second embodiment differs from the first embodiment in the number of the through holes.

Referring to FIG. 6A, a substrate body 55 is formed on a carrier 50. The dielectric layers 550 serve as a soft portion. They are formed on the carrier 50 by coating.

Referring to FIG. 6B, a plurality of conductive posts 62 and a block 69 are formed on the substrate body 55, and an insulating layer 64 is formed on the substrate body 55 to encapsulate the conductive posts 62 and the block 69. The surfaces of the conductive posts 62 and the block 69 are flush with the surface of the insulating layer 64 so as to be exposed from the insulating layer 64.

In an embodiment, the conductive posts 62 and the block 69 are made of metal, such as copper. Further, the conductive posts 62 and the block 69 can be made of the same or different materials.

Furthermore, the insulating layer 64 serves as a rigid portion and is formed by molding, coating or lamination. The insulating layer 64 is made of a dielectric material, such as an epoxy resin containing a molding compound or a primer, such as an epoxy molding compound. The epoxy molding compound contains 70 to 90 wt % of a filler.

In an embodiment, the dielectric layers 550 and the insulating layer 64 can be made of the same or different materials. In another embodiment, the dielectric layers 550 and the insulating layer 64 are made of the same or different kinds of epoxy resin.

Referring to FIG. 6C, the block 69 is removed to form a through hole 640 in the insulating layer 64. As such, a portion of the substrate body 55 is exposed from the through hole 640 to serve as a flexible section F, wherein the through hole 640 and the flexible section F form a cavity. Thereafter, the carrier 50 is removed. The conductive posts 62 and the insulating layer 64 can be regarded as an additional element 60.

In an embodiment, when the block 69 is removed by etching, portions of the conductive posts 62 are also removed so as to have end surfaces lower than the surface of the insulating layer 64. Further, a portion of the substrate body 55 can be removed to increase the depth of the through hole 640.

Further, when the carrier 50 is removed, an exposed portion of the electroplated copper layer (a portion of the circuit layer 551) of the flexible substrate body 55 can serve as an electromagnetic shielding layer 651, thereby eliminating the need to attach a silver adhesive conductive film as an electromagnetic shielding layer.

Subsequently, a surface treatment layer (not shown) can be formed on the conductive posts 62 according to the practical need.

Therefore, the substrate body 55 is directly formed on a single side of the carrier 50 and the number of the layers of the soft portion (the dielectric layer 550) or the rigid portion (the insulating layer 64) is optional and not limited by the symmetric additional layers on the two opposite sides of the core layer as in the prior art.

Further, the flexible substrate 6 has a rigid-flexible interface at a single side of the substrate body 55. At the rigid-flexible interface, two layers of epoxy resin (i.e., the dielectric layer 550 and the insulating layer 64) are directly bonded together so as to overcome the conventional drawbacks such as adhesive overflows, shorts and bulges and reduce flexural variations.

Furthermore, the coreless substrate body 55 greatly reduces the overall thickness of the flexible substrate 6. A four-layer board according to the present disclosure has a thickness d less than 0.2 mm, significantly less than the conventional four-layer board.

In addition, the outermost conductive pads of the flexible substrate 6 are copper posts (i.e., the conductive posts 62) and the dielectric material (i.e., the insulating layer 64) is used to replace the conventional solder mask layer. As such, the present disclosure strengthens the bonding between the conductive pads and the dielectric material, increases the subsequent wire bonding strength, and improves the product reliability and packaging capability.

Furthermore, the flexible section F is fabricated by image transfer in combination with pattern electroplating copper (block 69) and etching of copper (block 69). Therefore, the shape, size and accuracy of the flexible section F are not limited by the conventional mechanical machining process, thereby improving the freedom of the structural design. For example, a plurality of flexible sections F having any shape can be fabricated at the same time. Further, the block 69 and the conductive posts 62 can be fabricated together to reduce the fabrication cost.

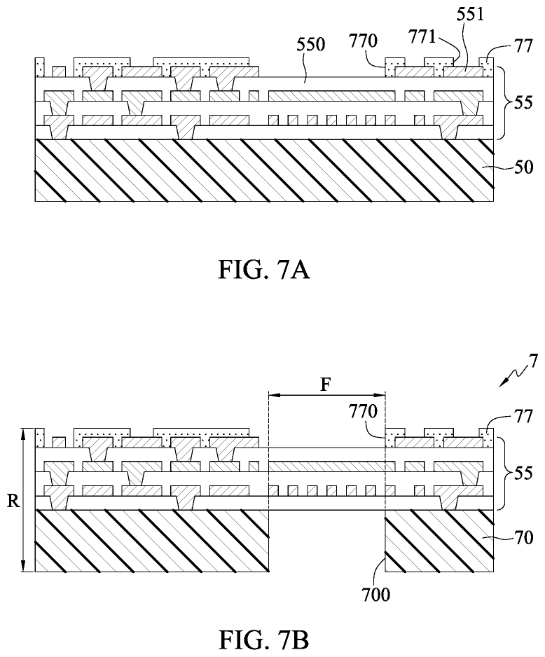

FIGS. 7A and 7B are schematic cross-sectional views showing a method for fabricating a flexible substrate 7 according to a third embodiment of the present disclosure. The third embodiment differs from the second embodiment in the fabrication of the through holes.

Referring to FIG. 7A, following FIG. 6A, an insulating layer 77 is formed on the substrate body 55. The insulating layer 77 has a plurality of openings 771 exposing the circuit layer 551 and at least an open area 770 exposing the dielectric layer 550. In an embodiment, the carrier 50 is a metal sheet.

Referring to FIG. 7B, a portion of the carrier 50 corresponding in position to the open area 770 is removed to form a through hole 700 penetrating the carrier 50 and exposing a portion of the substrate body 55. The carrier 50 having the through hole 700 serves as an additional element 70 (a rigid portion), and the exposed portion of the substrate body 55 serves as a flexible section F, wherein the through hole 700 and the flexible section F form a cavity.

Therefore, a metal sheet is used as the carrier 50 so as for a built-up process to be performed thereon. Further, a portion of the carrier 50 is retained and not removed to serve as an additional element 70 for supporting the rigid area and facilitating heat dissipation.

Further, the flexible substrate 7 has a rigid-flexible interface at a single side of the substrate body 55. At the rigid-flexible interface, the dielectric layer 550 and the carrier 50 made of metal are directly bonded together, and a portion of the carrier 50 is removed to form the through hole 700 penetrating the carrier 50. As such, the present disclosure overcomes the conventional drawbacks such as adhesive overflows, shorts and bulges at the rigid-flexible interface.

Furthermore, the flexible section F is fabricated by metal etching (removing a portion of the carrier 50). Therefore, the shape, size and accuracy of the flexible section F are not limited by the conventional mechanical machining process, thereby improving the freedom of the structural design. For example, a plurality of flexible sections F having any shape can be fabricated at the same time.

The coreless substrate body 55 greatly reduces the overall thickness of the flexible substrate 7. A four-layer board according to the present disclosure has a thickness R less than 0.2 mm, significantly less than the conventional four-layer board.

The present disclosure further provides a flexible substrate 5, 6, 7, which has a coreless substrate body 55 having a flexible section F and an additional element 5a, 5b, 60, 70 formed on the substrate body 55 and having a through hole 640, 700 (first and second through holes 530, 540) exposing the flexible section F.

In an embodiment, the substrate body 55 has at least a dielectric layer 550 and a circuit structure (for example, a circuit layer 551 and/or conductors 552) bonded to the dielectric layer 550.

In an embodiment, the additional element 5a, 5b, 60 has an insulating layer 64 (first and second insulating layers 53, 54) and a plurality of conductive posts 62 (first and second conductive posts 51, 52) embedded in the insulating layer 64. For example, the insulating layer 64 (the first and second insulating layers 53, 54) is made of a molding compound or a primer.

In an embodiment, the additional element 70 is a metal sheet.

According to the present disclosure, the coreless substrate body facilitates to reduce the overall thickness of the flexible substrate so as to meet the thinning requirement.

Further, at the rigid-flexible interface, the dielectric material is directly bonded to the additional element so as to overcome the conventional drawbacks such as adhesive overflows, shorts and bulges and improve the interlayer alignment accuracy.

Furthermore, since the circuit layer is formed through a semi-additive process without metal etching, the present disclosure facilitates impedance control and reduces the line width/pitch to meet the fine pitch/circuit requirement.

In addition, since the flexible section is defined by metal etching, the shape, size and accuracy of the flexible section F are not limited by the conventional mechanical machining process, thereby improving the freedom of the structural design.

The above-described descriptions of the detailed embodiments are only to illustrate the implementation according to the present disclosure, and it is not to limit the scope of the present disclosure. Accordingly, all modifications and variations completed by those with ordinary skill in the art should fall within the scope of present disclosure defined by the appended claims.

1. A flexible substrate, comprising:
a coreless substrate body having at least a dielectric layer as a soft portion, wherein a flexible section is defined by the dielectric layer, and the dielectric layer is made of a molding compound or a primer; and
an additional element as a rigid portion formed on the coreless substrate body with a through hole exposing the flexible section, wherein the through hole and the flexible section form a cavity.

2. The flexible substrate of claim 1, wherein the coreless substrate body further has a circuit structure bonded to the dielectric layer.

3. The flexible substrate of claim 1, wherein the additional element further has a conductive post embedded in an insulating layer.

4. The flexible substrate of claim 3, wherein the insulating layer is made of a dielectric material.

5. The flexible substrate of claim 4, wherein the dielectric material is a molding compound or a primer.

6. The flexible substrate of claim 1, wherein the additional element is a metal sheet.

7. A method for fabricating a flexible substrate, comprising:
providing a coreless substrate body having a flexible section and at least a dielectric layer;
forming an additional element on the coreless substrate body, wherein the additional element has an insulating layer, a conductive post embedded in the insulating layer, and a block penetrating the additional element; and
removing the block to form in the additional element a through hole exposing the flexible section, wherein the through hole and the flexible section form a cavity.

8. The method of claim 7, wherein the dielectric layer is made of a molding compound or a primer.

9. The method of claim 7, wherein the coreless substrate body further has a circuit structure bonded to the dielectric layer.

10. The method of claim 7, wherein the insulating layer is made of a dielectric material.

11. The method of claim 10, wherein the dielectric material is a molding compound or a primer.

12. A method for fabricating a flexible substrate, comprising:
forming a coreless substrate body on a carrier, wherein the coreless substrate body has a flexible section and at least a dielectric layer made of a molding compound or a primer; and
removing a portion of the carrier to form a through hole penetrating the carrier and exposing the flexible section for the carrier having the through hole to serve as an additional element, wherein the through hole and the flexible section form a cavity.

13. The method of claim 12, wherein the coreless substrate body further has a circuit structure bonded to the dielectric layer.

14. The method of claim 12, wherein the carrier is a metal sheet.
